(19) United States
(12) Patent Application Publication
(10) Pub. No.: US 2023/0018611 A1
(43) Pub. Date: Jan. 19, 2023

(54) BUSINESS-CARD TYPE DISPLAY DEVICE

(71) Applicant: NETRONIX, INC., JUBEI CITY (TW)

(72) Inventors: YI LI, HSINCHU CITY (TW); JUI HONG HUANG, JUBEI CITY (TW); LING LING WU, JUBEI CITY (TW); CHIEN TE HSIEH, JUBEI CITY (TW)

(21) Appl. No.: 17/505,786

(22) Filed: Oct. 20, 2021

(30) Foreign Application Priority Data
Jul. 16, 2021 (TW) 110208355

(51) Int. Cl. A44C 3/00; G09F 9/30; G09F 21/02; H05K 5/00; H05K 5/02

(52) U.S. Cl. CPC A44C 3/001; G09F 9/30; G09F 21/026; H05K 5/0017; H05K 5/0204

(57) ABSTRACT

A business-card type display device, connected to a sling that hangs on the body of a user, includes a display and a casing. The display has a display screen. The casing covers the display. The casing is provided with a display-installed portion therein. The surface of the casing is provided with a display opening whose position corresponds to the position of the display-installed portion. The surface of the casing is provided with a sling-connected portion above the display-installed portion. The sling-connected portion is connected to the sling. The display is installed in the display-installed portion. The display screen emerges from the display opening. The identification information displayed by the business-card type display device can be rapidly changed, which is very effective in use.

This application claims priority of Application No. 110208355 filed in Taiwan on 16 Jul. 2021 under 35 U.S.C. § 119; the entire contents of all of which are hereby incorporated by reference.

### BACKGROUND OF THE INVENTION

### Field of the Invention

The present invention relates to a display, particularly to a business-card type display device for identification.

### Description of the Related Art

Enterprises pay attention to the control of personnel and the confidentiality of the company's internal information. In order to prevent unscrupulous persons from invading the company, they usually use an access card or an identification card as a certificate to enter the company. The certificate is viewed as first-level security. It is also convenient for internal colleagues to identify the flow of personnel.

At present, most of the existing personal hanging nameplates use ink to print basic personal information on plastic or traditional papers. Therefore, when personnel change or new personnel want to use them, it is necessary to discard the old nameplates and reproduce new ones. In the long run, the waste of material costs and environmental pollution will be caused.

To overcome the ahovementioned problems, the present invention provides a business-card type display device, so as to solve the aforementioned problems of the prior art.

### SUMMARY OF THE INVENTION

The primary objective of the present invention is to provide a business-card type display device, which is used as a nameplate or an identification card. The information displayed by the business-card type display device can be rapidly changed, which is very effective in use.

Another objective of the present invention is to provide a business-card type display device, which reduces the waste of ink and paper used in the traditional printing of business cards in the past. The business-card type display device has great environmental value and protects the earth's environment.

In order to achieve these objectives, the present invention provides a business-card type display device connected to the sling that hangs on a body of a user. The business-card type display device includes a display and a casing. The display has a display screen. The casing covers the display. The casing is provided with a display-installed portion therein. The surface of the casing is provided with a display opening whose position corresponds to the position of the display-installed portion. The surface of the casing is provided with a sling-connected portion above the display-installed portion. The sling-connected portion is connected to the sling, and the display is installed in the display-installed portion. The display screen emerges from the display opening.

In an embodiment of the present invention, the casing is further provided with a button opening, and a display switch of the display emerges from the button opening.

In an embodiment of the present invention, the button opening is arranged on a top of the casing and arranged at a side of the casing corresponding to the sling-connected portion.

In an embodiment of the present invention, the casing is further provided with a port opening and a signal port emerges from the port opening.

In an embodiment of the present invention, the port opening is arranged on the top of the casing and arranged at a side of the casing corresponding to the sling-connected portion.

In an embodiment of the present invention, the display is an electronic paper.

In an embodiment of the present invention, the top of the display is further provided with a port opening and a display switch.

Below, the embodiments are described in detail in cooperation with the drawings to make easily understood the technical contents, characteristics and accomplishments of the present invention.

### BRIEF DESCRIPTION OF THE DRAWINGS

FIG. 1 is a perspective view of a business-card type display device according to an embodiment of the present invention;

FIG. 2 is an exploded view of a business-card type display device according to an embodiment of the present invention; and

FIG. 3 is a schematic diagram illustrating the state of using a business-card type display device according to an embodiment of the present invention.

### DETAILED DESCRIPTION OF THE INVENTION

The business-card type display device of the present invention is used as a nameplate or an identification card. The information displayed by the business-card type display device can be rapidly changed, which is very effective in use. The present invention can reduce the waste of ink and paper used in the traditional printing of business cards in the past. The business-card type display device has great environmental value and protects the earth's environment.

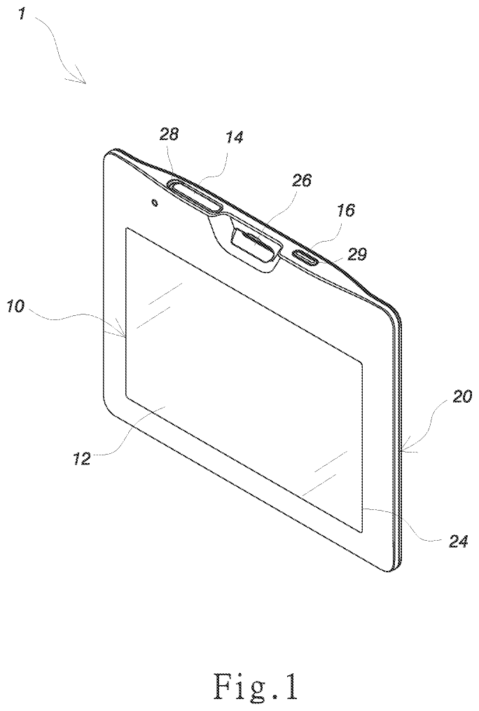

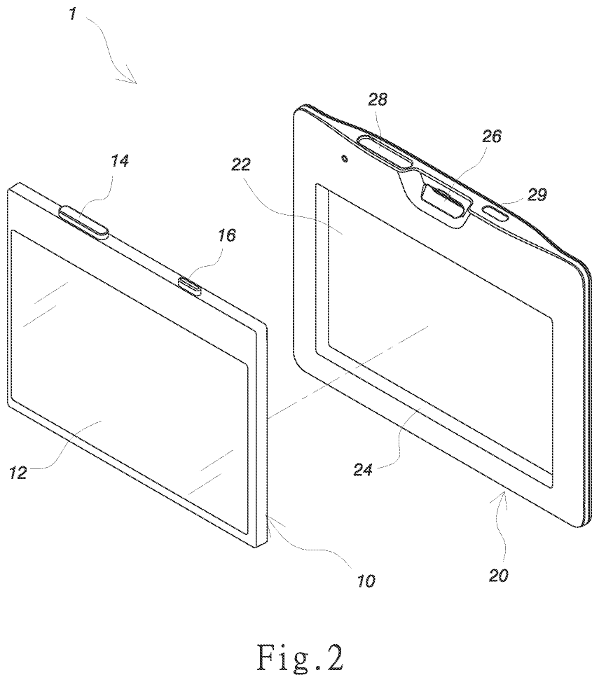

The structure of the display device of the present invention is introduced to describe how to achieve the foregoing effect. Referring to FIG. 1 and FIG. 2, a business-card type display device 1 connected to a sling (not shown) that hangs on the body of a user. As shown in FIG. 1 and FIG. 2, the business-card type display device 1 includes a display 10 and a casing 20. The display 10 may be an electronic paper. The display 10 has a display screen 12. In the embodiment, the top of the display 10 is provided with a display switch 14 and a port opening 16. The display switch 14 and the port opening 16 are located on any position of the display 10. The present invention is not limited to the positions where the display switch 14 and the port opening 16 are located.

The casing 20 covers display 10. The casing 20 is provided with a display-installed portion 22, a display opening 24, a sling-connected portion 26, a button opening 28, and a port opening 29. The display-installed portion 22 is located within the casing 20. The surface of the casing 20 is provided with the display opening 24 whose position corresponds to the position of the display-installed portion 22. The display 20 can be installed in the display-installed portion 22, The display screen 12 of the display 10 can emerge from the display opening 24 of the casing 20.

The sling-connected portion 26 is located on the casing 20 and above the display-installed portion 22, The sling-connected portion 26 can be connected to a sling (not shown). The business-card type display device 1 is connected to the sling that hangs on the body of a user, such as the chest of the user.

The button opening 28 is arranged on the casing 20. The display switch 14 of the display 10 emerges from the button opening 28, In the embodiment, the position of the button opening 28 corresponds to that of the display switch 14. The button opening 28 is arranged on the top of the casing 20 and arranged at a side of the casing 20 corresponding to the sling-connected portion 26. The present invention is not limited to the position of the button opening 28.

The port opening 29 is arranged on the casing 20. The signal port 16 of the display 10 emerges from the port opening 29. The position of the port opening 29 corresponds to that of the signal port 16, The port opening 29 is arranged on the top of the casing 20 and arranged at a side of the casing 20 corresponding to the sling-connected portion 26. The present invention is not limited to the position of the port opening 29.

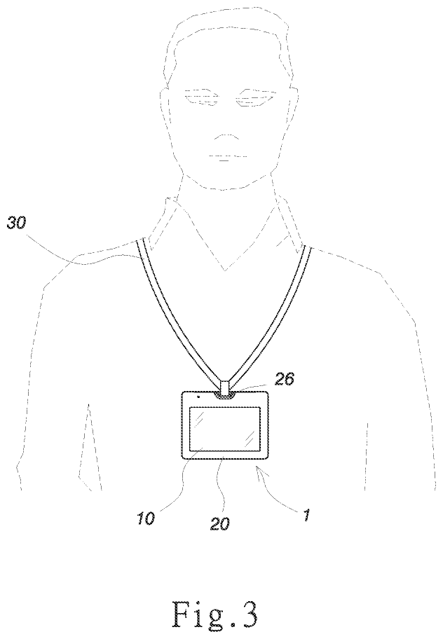

After describing the structure of the present invention, the state of using the business-card type display device 1, Referring to FIG. 3, the business-card type display device 1 is connected to a sling 30 when in use. The user hangs the business-card type display device 1 around his/her neck through the sling 30, and uses the business-card type display device 1 as a nameplate or an identification card.

In conclusion, the business-card type display device of the present invention is used as a nameplate or an identification card. The information displayed by the business-card type display device can be rapidly changed, which is very effective in use. The present invention can reduce the waste of ink and paper used in the traditional printing of business cards in the past. The business-card type display device has great environmental value and protects the earth's environment.

The embodiments described above are only to exemplify the present invention but not to limit the scope of the present invention. Therefore, any equivalent modification or variation according to the shapes, structures, features, or spirit disclosed by the present is to be also included within the scope of the present invention.

What is claimed is:

1. A business-card type display device, connected to a sling that hangs on a body of a user, comprising:
a display having a display screen; and
a casing covering the display, wherein the casing is provided with a display-installed portion therein, a surface of the casing is provided with a display opening whose position corresponds to a position of the display-installed portion, a surface of the casing is provided with a sling-connected portion above the display-installed portion, the sling-connected portion is connected to the sling, the display is installed in the display-installed portion, and the display screen emerges from the display opening.

2. The business-card type display device according to claim 1, wherein the casing is further provided with a button opening and a display switch of the display emerges from the button opening.

3. The business-card type display device according to claim 2, wherein the button opening is arranged on a top of the casing and arranged at a side of the casing corresponding to the sling-connected portion.

4. The business-card type display device according to claim 1, wherein the casing is further provided with a port opening and a signal port emerges from the port opening.

5. The business-card type display device according to claim 4, wherein the port opening is arranged on a top of the casing and arranged at a side of the casing corresponding to the sling-connected portion.

6. The business-card type display device according to claim 1, wherein the display is an electronic paper.

7. The business-card type display device according to claim 1; wherein a top of the display is further provided with a port opening and a display switch.
